(19) United States
(12) Patent Application Publication
(10) Pub. No.: US 2010/0226163 A1
(43) Pub. Date: Sep. 9, 2010

(54) Method of resistive memory programming and associated devices and materials

(76) Inventor: Semyon D. Savransky, Newark, CA (US)

Correspondence Address: Daniel R. Shepard;Contour Semiconductor, Inc, Blgd 5, 101 Billerica Ave., No. Billerica, MA, 01862, US

(21) Appl. No.: 12/660,782

(22) Filed: Mar. 3, 2010

Related U.S. Application Data
(60) Provisional application No. 61/209,191, filed on Mar. 4, 2009.

(51) Int. Cl. G11C 11/00; G11C 7/22; H01L 45/00; H01L 29/12

(52) U.S. Cl. 365/148; 365/189.16; 257/4; 252/62.3 R; 257/E45.001

(57) ABSTRACT

A pulse coupled with a microwave field is used for programming a resistive memory into one of non-volatile states. As the result, the programming becomes faster and more energy efficient. Related devices and materials are also described.

### CROSS REFERENCE TO RELATED APPLICATIONS

This application claims priority to and the benefit of, and incorporates herein by reference in its entirety, U.S. Provisional Patent Application No. 61/209,191, which was filed on Mar. 4, 2009.

### REFERENCE TO A SEQUENCE LISTING, A TABLE, OR A COMPUTER PROGRAM LISTING COMPACT DISK APPENDIX

Not Applicable.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### BACKGROUND OF THE INVENTION

1. Field of the Invention

Resistive memory based on reversible transition of active material between two or more non-volatile states, for example phase-change memory.

2. Description of Related Art

Integrated circuit designers have always sought the ideal memory: a device that is randomly accessible, can be written or read very quickly, is non-volatile, but indefinitely alterable, consumes little power, can be produced cheaply by regular semiconductor process, and is scalable. The search for such devices has led to research and development of different resistive memories, such as MRAM, FeRAM (sometimes called FRAM), PCM (sometimes called PRAM or PCRAM or PC-RAM), molecular memory, polymer memory, ion-conducting memory (PMC), memristive memory, spin memory, oxide memory (OxRAM or RRAM or ReRAM), conductive bridging random access memory (CBRAM).

A generic resistive memory device 100 consists of an active material 110 between two electrically conductive electrodes 120 and 130 as shown in FIG. 1. The active material can be a phase change alloy, e.g. Ge—Sb—Te; or an ion conductor, e.g. Cu—Ge—Se; or a binary metal-oxide, e.g. TiO2, or a ternary metal-oxide, or a more complicated metal-oxide, or a ferroelectric, or a perovskite, or a marnetoresistor, e.g. a colossal magnetoresistive (CMR) film, a transition metal oxide, a Mott insulator.

The electrodes can be made from any material with good electrical conductivity, e.g., from metal such as W, Ag, Al, Ti or Cu.

The known resistive memories work due to reversible transitions of the active material between two or more non-volatile states with different properties. Each of the non-volatile states can be coded as logical state. The transition occurs during programming pulses applied between the electrodes to the active material. For example, a phase-change memory (PCM) works due to reversible transition between nano-crystalline and glassy phases of phase change alloy (PCA). PCM can be programmed to low resistance set (mostly crystalline) state or to high resistance reset (mostly glassy) state by so-called set or reset pulses (FIG. 2). The set state can be coded as logical 0 and the reset state can be coded as logical 1.

Although physical processes responsible for the reversible transitions and therefore terminology for different types of resistive memories are different, we use the terminology of PCM type of the resistive memory for consistency. Anybody skilled in the art can easily transform the terminology to another type of the resistive memory. Anybody skilled in the art can easily figure out how to program a resistive memory into more that 2 logical states. For the sake of simplicity, we use mainly terminology for 2 logical states (namely, a set state and a reset state) of simplest PCM.

The transition from the glassy to the crystalline phase occurs in PCM due to crystallization initiated by long electrical pulse (typically 500 ns) with a moderate electrical current that heats up PCA to or above crystallization temperature Tx during the set pulse. Because the set pulse (FIG. 2) is long PCM cannot compete with fast memories such as SRAM and high-performance DRAM.

U.S. Pat. Nos. 6,075,719, 6,487,113, 6,570,784, 6,687,153 describe methods of PCM programming into low resistance crystalline set state by different electrical set pulses. But all these pulses are long that limits usage PCM as fast high performance memory.

There have been few attempts to reduce set time by choosing PCA with fast crystallization, but such PCA do not satisfy other requirements of a non-volatile memory.

What is needed in the art is a method of programming of a resistive memory (including PCM) by a fast pulse, e.g. set pulses for PCM with duration below 100 ns.

The transition from the crystalline to glassy phase in known methods of PCM programming occurs due to melting initiated by short electrical pulse (typically 50 ns) with a high electrical current about 1 mA that heats up PCA above melting point Tm and fast PCA cooling below glass transition temperature Tg during the reset pulse (FIG. 2).

U.S. Pat. No. 7,272,037 and application 20090003035, 20080273371 describe methods of PCM programming into high resistance glassy reset state by different electrical reset pulses. But all these pulses required heating PCA above the melting temperature Tm.

Because Tm is higher than Tx the reset current is larger than set current. High reset current is the main disadvantage of PCM to compare with other non-volatile memories, such as FLASH memory.

There have been few attempts to reduce reset current by choosing PCA with small melting temperature, but such PCA do not satisfy other requirements of a non-volatile memory.

There have been several attempts to reduce reset current by decreasing glassy region in PCM due to scaling of area between PCM electrode and active PCA volume. This approach required expensive photo-lithography or other methods to make characteristic device features as small as 32 nanometers.

There have been few attempts to reduce reset current by designing PCM with high thermal efficiency, but the best achieved efficiency of PCM is still less than 10 percent.

What is needed in the art is a method of programming of a resistive memory (including PCM) by low-energy pulses, e.g. reset pulses for PCM with small current below 100 uA.

In all cases of prior art the pulses or pulse trains produce current through PCM during set or reset programming. This current heats up active PCA to or above crystallization temperature Tx for the set state and to or above melting temperature Tm for the reset state due to the Joule effect.

Microwave electromagnetic fields (MWF) are often used in semiconductor devices and particular memory devices manufacturing (e.g., U.S. Pat. Nos. 4,158,807, 5,330,630, 6,891,138, 7,394,090 and US Patent Applications 20070218583, 20070235714, 20080135162).

MWF can heat poly- and nano-crystals as well as glasses effectively. MWF can be used in a synthesis of organic and inorganic materials, such as nano-porous zeolites. MWF can accelerate crystallization of glasses is used for glass-ceramics and special coatings manufacturing. These three types of events occur due to thermal and non-thermal (athermal) effects of MWF. Although the nature of the non-thermal effects of MWF is still not well established it is used in practice, see e.g., U.S. Pat. Nos. 6,537,481, 6,350,973, 6,344,635, 6,344,634, 6,344,120.

Campbell, et. al. proposed to use MWF absorption spectroscopy for reading of a resistive memory in U.S. Pat. Nos. 7,105,864 and 7,366,030 but they did not consider to use microwaves for programming of a memory.

Microwave electromagnetic fields were not applied to programming of a semiconductor memory and in particular of a resistive memory in the prior art.

### SUMMARY OF THE INVENTION

Broadly speaking, the embodiments of the present invention fill industry needs by providing methods for fast and low energy programming a resistive memory. In particular, the present invention fill industry needs for fast a phase change memory into set state and for programming a phase change memory into reset state with small current.

Some embodiments use new ways to obtain the different logical states in a resistive memory by means of programming the active material by pulses coupled with microwave electromagnetic field (MFW). MWF provides bulk heating of the active material in contrast with Joule heating that occurs mostly at interface between electrodes and the active material. Therefore, MWF heating is more efficient for many types of memory devices. According to some embodiments of the invention, the programming a phase-change memory occurs due to the non-thermal microwave effects such as non-thermal heating or crystallization by application pulses coupled with a MWF to PCA.

During a small power reset pulse coupled with MWF the initially mostly nano-crystalline PCA reaches temperatures lower than Tm, yet PCM resistance still changes to the high value in one or more embodiments.

During a short set pulse coupled with MWF the initially mostly glassy PCA can crystallize during this short period of time, and PCM resistance changes to the low value in one or more embodiments.

New materials that increase an efficiency of the microwave field based programming of a resistive memory are used in some embodiments of the present invention.

New constructions of resistive memory storage and retrieval device are described in some embodiments of the present invention.

It should be appreciated that the embodiments of the invention can be implemented in numerous ways, including as a process, an apparatus, a system, or a device.

It should be appreciated that the embodiments of the invention can be implemented in different resistive memories, including a PCM, a MRAM, a FeRAM, a PMC, molecular memory, polymer memory, ion-conducting memory, memristive memory, or a RRAM named a few.

### BRIEF DESCRIPTION OF THE DRAWINGS

The invention is illustrated by way of example and not by way of limitation in the figures of the accompanying drawings in which like references indicate similar elements. It should be noted that references to “an” embodiment in this disclosure are not necessarily to the same embodiment, and they mean at least one.

FIG. 1 shows a generic resistive memory device.

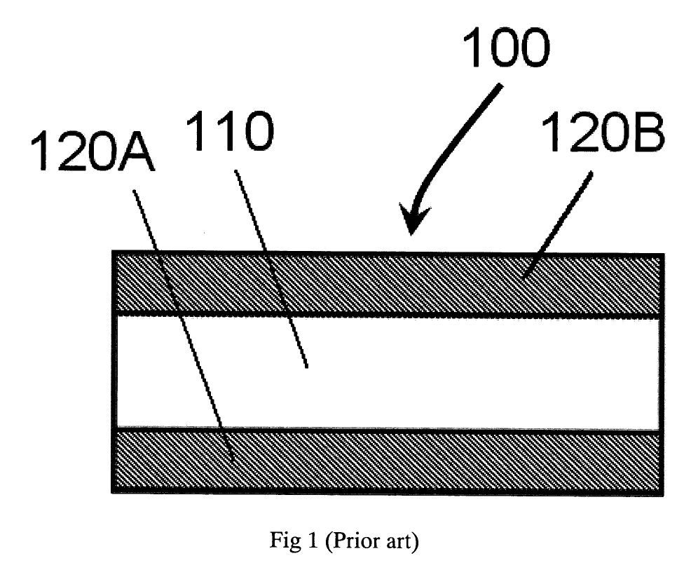

FIG. 2 shows a conventional sequence of pulses for programming a phase-change memory. The levels of reset and set currents are shown for the comparison.

FIG. 3A illustrates a reset programming pulse according to an embodiment of the invention.

FIG. 3B illustrate reset pulse according to one or more embodiments of the invention.

FIG. 3C shows a comparison between a current of the reset pulse according to an embodiment of the invention and reset and set currents for pulses known in prior art.

FIG. 4A illustrates a set programming pulse according to an embodiment of the invention.

FIG. 4B illustrates a set pulse according to one or more embodiments of the invention.

FIG. 4C shows a comparison between a duration of the set pulse according to an embodiment of the invention and durations of reset and set pulses known in prior art.

FIG. 5 shows a memory storage and retrieval device according to an embodiment of the invention.

FIG. 6 show examples of memory array with a write circuit, a microwave generator and other interface devices, according to one or more embodiments of the invention.

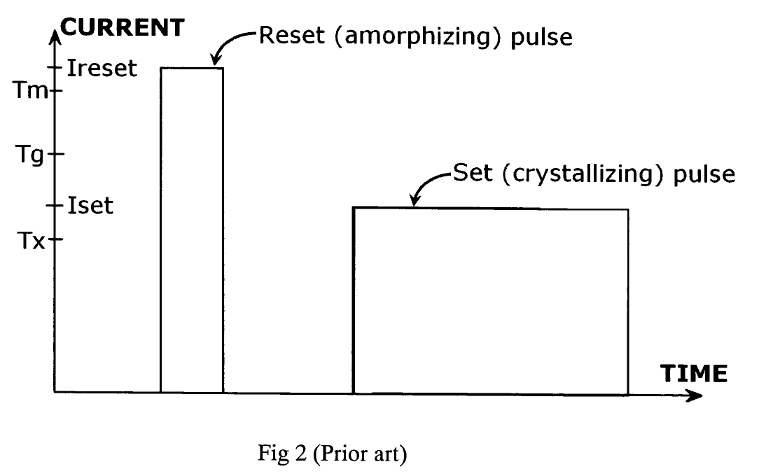

FIGS. 2-5 show temperature or current along the vertical axis. It should be understood that the vertical axis could also show the voltage, energy, heat, pressure, acoustic or magnetic field, gravity force or other type of input amplitude of the respective signal.

### DETAILED DESCRIPTION

Several exemplary embodiments of the invention will now be described in details with reference to the accompanying drawings.

For the sake of simplicity only phase change memory is described in details below, although one or more embodiments of the invention are applicable for other types of resistive memory, such as MRAM, FeRAM (sometimes called FRAM), PCM (sometimes called PRAM or PCRAM or PC-RAM), molecular memory, polymer memory, ion-conducting memory (PMC), memristive memory, spin memory, oxide memory (OxRAM or RRAM or ReRAM), conductive bridging random access memory (CBRAM). Anybody skilled in the art can easily adopt the proposed methods, compounds, devices and apparatuses of one or more embodiments of this invention to resistive memories different from the phase change memory.

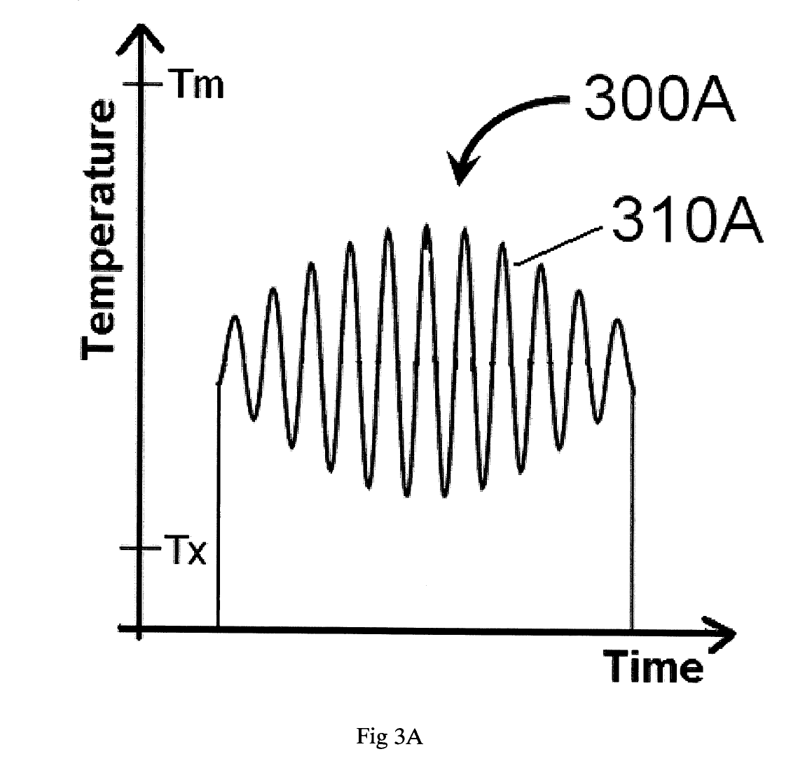

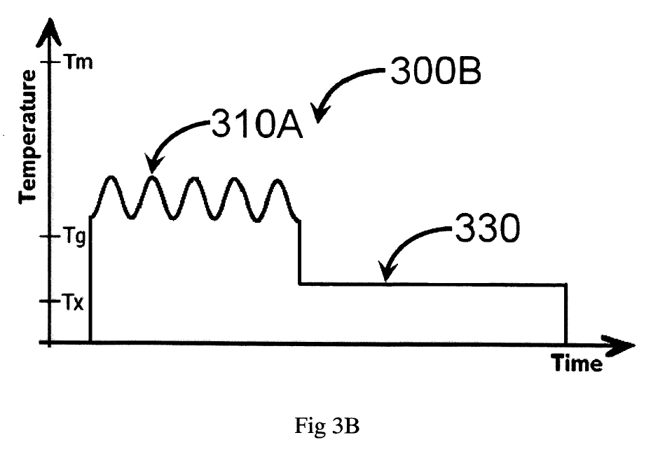

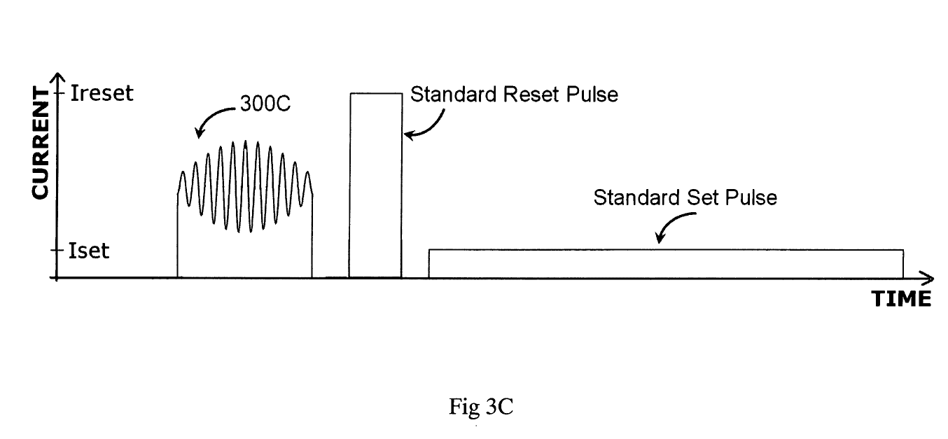

FIG. 3 show reset pulses 300A, 300B, and 300C for a PCM. Each of these reset pulses coupled with a microwave electromagnetic field (MWF) programs the phase-change memory in the reset states with relatively high resistance and threshold voltage to compare with the set states of PCM. MWF provides bulk quite uniform within a device volume heating of the active material in contrast with Joule heating that occurs mostly at interface between electrodes and the active material. Therefore, MWF heating is more efficient for many types of nanoscale memory devices.

FIG. 3A illustrates a reset pulse 300A. Hybrid heating by Joule effect and microwave field 310A brings PCA below the melting temperature Tm but above PCA crystallization temperature Tx during the reset pulse 300A according to one or more embodiments of the invention. MWF amplitude 310A is changing during the pulse 300A. PCA is excited by the microwave field and by electrical current through a PCM device during the same time as shown in FIG. 3A.

FIG. 3B illustrates a reset pulse 300B. Hybrid heating by Joule effect and microwave field 310B brings PCA below the melting temperature Tm but above the glass transition temperature Tg during the reset pulse 300B according to one or more embodiments of the invention. MWF amplitude 310B is constant during the pulse 300B. The electrical current flows through a memory device for a period of time 330 after MWF duration 310B during the pulse 300B.

FIG. 3C compares amplitude of a reset pulse coupled with MWF 300C with the amplitudes of standard reset and set pulses.

The amplitude of the reset pulse coupled with MWF is smaller than an amplitude of a standard reset pulse (without MWF). The amplitude of the standard reset pulse is big enough to melt a portion of PCA during the programming of PCM.

Nevertheless the MWF coupled reset pulses 300A, or 300B or 300C lead to the same PCA properties (e.g. high electrical resistance) as PCA properties obtained by standard reset pulses. The duration of the MWF coupled reset pulses is below 100 ns.

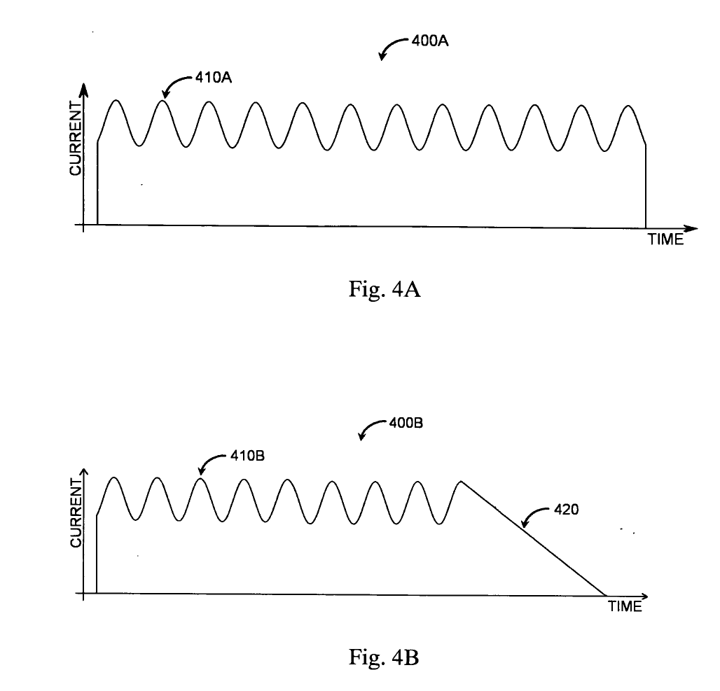

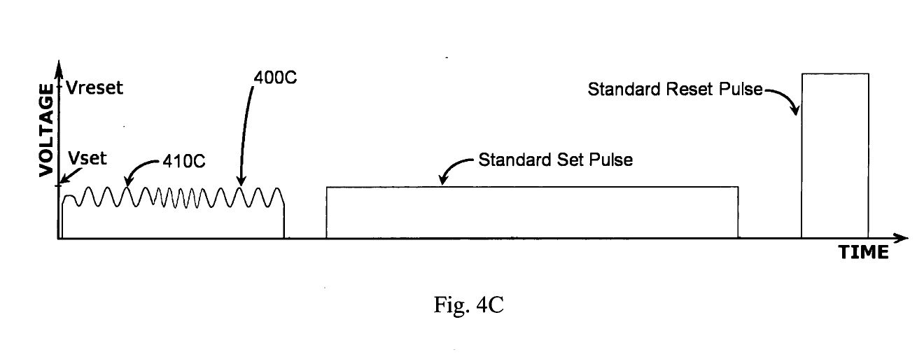

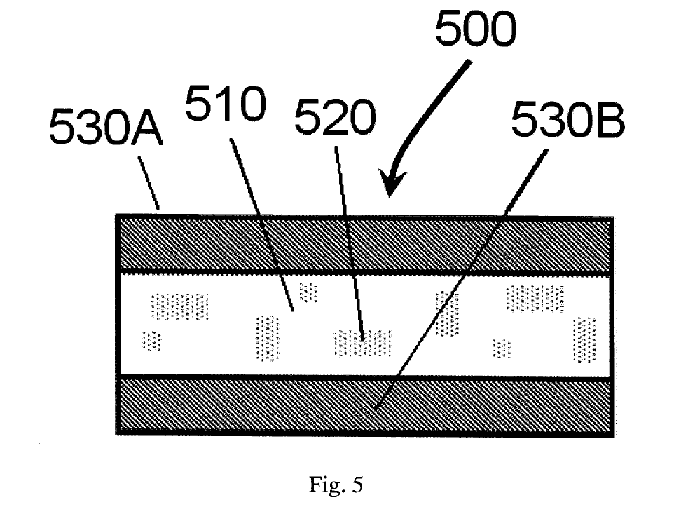

FIG. 4 show set pulses 400A, 400B, and 400C for a PCM. Each of these set pulses coupled with MWF programs the phase-change memory in the set states with relatively small resistance and threshold voltage to compare with the reset states of PCM.

FIG. 4A illustrates a set pulse 400A. Hybrid heating by Joule effect and microwave field 410A brings PCA to crystallization temperature Tx during the set pulse 400A according to one or more embodiments of the invention. The amplitude and frequency of MWF 410A are constant during the set pulse 400A as shown in FIG. 4A.

FIG. 4B shows a set pulse 400B. The set pulse 400B compromising at least 2 parts: first when MWF excites PCA 410B and second 420 when MWF amplitude is zero. PCA is excited by electrical current through a PCM device for longer time than by the microwave field as shown in FIG. 4B according to one or more embodiments of the invention.

FIG. 4C compares duration of a set pulse coupled with microwave field 400C with the amplitudes of standard reset and set pulses (without MWF). The amplitude or/and frequency of MWF 410C is/are varied during the set pulse 400C according to one or more embodiments of the invention. Due to non-thermal effect of MWF crystallization of PCA occurs faster for the set pulse 400C than for standard set pulse.

Duration of the set pulse coupled with MWF is shorter that duration of a standard set pulse (without MWF). Nevertheless the MWF coupled set pulses 400A, or 400B or 400C lead to crystallization of PCA during PCM. The MWF coupled set pulses 400A, or 400B or 400C lead to the same PCA properties (e.g. low electrical resistance) as PCA properties obtained by standard set pulses.

Any of the MWF coupled pulses 300A, 300B, 300C, 400A, 400B or 400C is belong to the group consisting of square pulses, non-rectangular pulses, and free shaped pulses with uniform or non-uniform segments. Any of the MWF coupled pulses 300A, 300B, 300C, 400A, 400B or 400C is a member of group consisting of electric current or voltage, temperature, pressure and any of other signals. The electric current or voltage can be bipolar or unipolar (has a single polarity). Any of the MWF coupled pulses 300A, 300B, 300C, 400A, 400B or 400C can be a single pulse or plural pulses or train(s) of pulses.

MWF amplitude is variable during the MWF coupled set pulse or the MWF coupled reset pulse according to one or more embodiments of the invention.

MWF frequency is variable during the MWF coupled set pulse or the MWF coupled reset pulse according to one or more embodiments of the invention.

The amplitude and frequency of MWF are variable during the MWF coupled set pulse or the MWF coupled reset pulse according to one or more embodiments of the invention.

MWF amplitude changes during the MWF coupled set pulse or the MWF coupled reset pulse according to one or more embodiments of the invention.

MWF frequency changes during the MWF coupled set pulse or the MWF coupled reset pulse according to one or more embodiments of the invention.

The amplitude and frequency of MWF change during the MWF coupled set pulse or the MWF coupled reset pulse according to one or more embodiments of the invention.

Duration of MWF is shorter, or equal, or longer than the duration of the set pulse or the reset pulse according to one or more embodiments of the invention.

MWF during the MWF coupled set pulse has a frequency in the range from 300 MHz to 300 GHZ according to one or more embodiments of the invention.

MWF frequency corresponds to maximum non-thermal microwave heating effect for a set state of PCM according to one or more embodiments of the invention.

MWF frequency corresponds to maximum non-thermal microwave crystallization effect for a reset state of PCM according to one or more embodiments of the invention.

Any of the MWF coupled pulses 300A, 300B, 300C, 400A, 400B or 400C transforms an active material of a memory device between at least two states that can be coded as logic 0 and logic 1. These two states includes one or more states there a subsystem of the active material is mostly disordered, and one or more states there the subsystem of the active material is at least partially ordered. The subsystem is selected from the group consisting of atomic, electron, electric or magnetic dipole subsystem of the active material. These states have one or more properties with values different from a predetermined value for this property. According to one or more embodiments of the invention the property can be any member of group consisting of electrical resistance, electrical impedance, threshold switching voltage, electrical capacitance, electrical inductance, optical reflection, signal of electron spin resonance, and others signals that can be detected.

For example, in a phase-change alloy the subsystem consist of atoms which configuration is more disordered in the reset states of PCM and more ordered in the set states of PCM, while the property is resistance that is higher for the reset states than for the set states of PCM.

The abovementioned set states, have one or more properties with values below a predetermined value for this property; and one or more said reset states, have one or more properties with values above the predetermined value for this property.

For example, a reset state of PCM has the threshold switching voltage above the predetermined voltage; and a set state of PCM has the threshold switching voltage below the predetermined voltage. The predetermined voltage for PCM can be about 0.5V.

The abovementioned active material can be a phase change alloy, e.g. Ge—Sb—Te; or an ion conductor, e.g. Cu—Ge—Se; or a binary metal-oxide, e.g. TiO2, or a ternary metal-oxide, or a more complicated metal-oxide, or a ferroelectric, or a perovskite, or a marnetoresistor, e.g. a colossal magnetoresistive (CMR) film, a transition metal oxide, a Mott insulator.

According to one or more embodiments of the invention a compound compromises a host material capable to reversible transition between two or more non-volatile states, and a susceptor dispersing in the body of the host material. The susceptor can be used when host material do not absorb microwave radiation. The susceptor is an inert compound with or without a resistive memory capability that efficiently absorbs radiation from MWF and transfers the thermal energy to host material. The susceptor increase efficiency of MWF when the coupling of MWF with the host material is not strong enough.

The host material and the susceptor coupled together in the compound by a method selected from the group consisting of mixing, co-deposition, and co-melting.

The examples of the host material are phase-change alloys, polymers with memory effect, ion conductors, organic and inorganic ferroelectric, or perovskite or memristive materials, ferroelectrics, binary, ternary or even more complicated metal-oxides, magnetoresistive materials, transition metal oxides, Mott insulators, chalcogenide or pnictide alloys containing Te or Sb. The phase change alloy compromises chemical elements selected from the group consisting of Ge, Sb, Te, Se, Si, As, Ga, Sn, Bi, and In, e.g., Ge—Sb—Te or In—Sb—Te.

The host material can be from about 1 nm to about 100 um thick in one or more embodiments of the invention

The susceptor is inorganic or organic (e.g., polymer) or mixed in one or more embodiments of the invention.

The examples of the susceptors are carbon, SiC, metals and an electrostrictive materials. The metals are selected from the group consisting of Mn, Co, Cr, Fe, Cu, Zn, Ti, Hf, V, Cd, Ni and materials containing ions of these metals in one or more preferred embodiments of the invention. The electrostrictive material selected from the group consisting of lead magnesium niobate (PMN), lead magnesium niobate-lead titanate (PMN-PT), and lead lanthanum zirconate titanate (PLZT) in one or more preferred embodiments of the invention.

The susceptor does not chemically interact with the host material even in it molted state in one or more preferred embodiments of the invention.

The susceptor has higher melting temperature than a melting temperature of the host material in one or more preferred embodiments of the invention.

Depending on the selection of the host material the susceptor fills from 0.1% to 30% of the host material volume in one or more embodiments of the invention.

A selection of the host and susceptor depends on the type of memory and on the parameters of MWF such as frequency or amplitude. Both host and susceptor should be tuned to an apparatus used to program memory. Anybody skilled in the art can easily figure out best host and susceptor pair for particular memory. More than one type of susceptors can be used with the same host in the same memory device. Some embodiments of the apparatus are described in details later in this section.

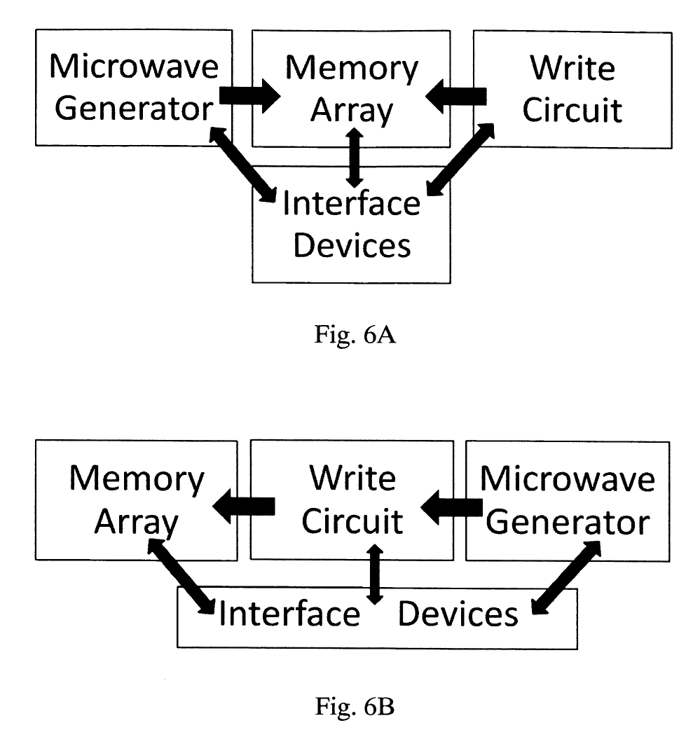

FIG. 5 illustrates a generic memory storage and retrieval device 500, according to one or more embodiments of the invention. The device 500 compromises at least one active material 510 with susceptor 520 dispersing in its body with at least one of electrodes 530A and 530B coupled with the active material 510.

Conductive electrodes 530A and 530 are in mechanical and electrical contacts with the active material 510. The abovementioned compounds can be used as active material 510. The electrodes 530 can be made from a metal (e.g., Ti or Pt or Pt—Ir or Mo), conductive carbon or conductive composite (e.g., TiSN or TiSiAl).

The examples of the active material 510 are phase-change alloys, polymers with memory effect, ion conductors, organic and inorganic ferroelectric, or perovskite or memristive materials, ferroelectrics, binary, ternary or even more complicated metal-oxides, magnetoresistive materials, transition metal oxides, Mott insulators, chalcogenide or pnictide alloys.

The active material 510 consists of at least one pnictogen (for example, Sb) or at least one chalcogen (for example, Te) in one or more embodiments. The active material 510 can contain one or more chemical elements (for example, H, F, In, Sn, Bi) that form atomic bond with a pnictogen or/and a chalcogen with energy smaller than the energy of the bond between said pnictogen and chalcogen. The atomic structure of said phase change alloy is easily deformable by external pressure due to significant concentration of vacancies and it examples are H—Sb—Te or F—Sb—Se—Te or Ge—Sb—Te or Bi—Sb—Te or In—Sb—Te or Sb—In—Ge—Te. The active material 510 can contain one or more chemical elements selected from the group consisting of Ge, Sb, Te, Se, Si, As, Ga, Sn, Bi.

The susceptor 520 interacts strongly with microwave field. They can be made from C, SiC, Mn, Co, Cr, Fe, Cu, Zn, Ti, Hf, V, Cd, Ni, water or organic material in one or more embodiments. The susceptor can be made from a electrostrictive material, such as lead magnesium niobate (PMN), lead magnesium niobate-lead titanate (PMN-PT) or lead lanthanum zirconate titanate (PLZT) in other embodiments.

The coefficients of thermal expansion and the compressibilities of the electrodes 530 are smaller than the coefficients of thermal expansion and the compressibility of the active material 510 with the embedded susceptor 520. The hardness (for example, Brinell hardness) and elastic modulus of the active material 510 with the embedded susceptor 520 are smaller than hardnesses and elastic modules of the electrodes 530 in the device 500.

The programming of the memory device 500 into different states occurs by relatively short and low energy abovementioned MWF coupled pulses or by above-mentioned standard pulses known in the art.

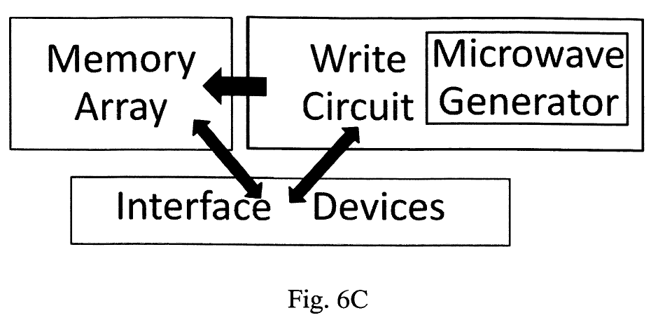

A write circuit and a microwave generator can be connected with the device 500 in order to provide abovementioned MWF coupled pulses for programming. More effective way is electrically connect the microwave generator and the write circuit with a memory array that consist of plurality of devices 500 as shown in FIG. 6. The write circuit and the microwave generator provide set and reset pulses described in the previous sections. The write circuit and the microwave generator are coupled in some embodiments. The microwave generator is embedded in the write circuit in some embodiments. The memory array, the microwave generator and the write circuit are coupled with an interface device, e.g. with a computer or a music player in some embodiments. The memory array, and the write circuit with the embedded microwave generator are coupled with an interface device, e.g. with a personal digital assistance or a mobile phone in some embodiments. In some embodiments the microwave generator and the write circuit are connected with arrays from same or different types of resistive memory, e.g., from phase change memory, metal-oxide memory, molecular memory. Anybody skilled in the art can easily choose or design the specially constructed or/and general-purpose microwave generator, write circuit, and memory array. Anybody skilled in the art can design specially constructed microwave generator embedded in write circuit for a memory array.

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of portions and/or steps and/or segments may be exaggerated for clarity.

It will be understood that, although the terms first, second, third etc. may be used herein to describe various portions and/or steps and/or segments, these portions and/or steps and/or segments should not be limited by these terms. These terms are only used to distinguish one portion and/or step and/or segment from another portion and/or step and/or segment. Thus, a first portion and/or step and/or segment discussed below could be termed a second portion and/or step and/or segment without departing from the teachings of the present invention.

Temporary relative terms, such as “after,” and “before” and the like, may be used herein for ease of description to describe one portions and/or steps and/or segments or feature's relationship to another portions and/or steps and/or segments(s) or feature(s) as illustrated in the figures.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated portions and/or steps and/or segments and/or features, but do not preclude the presence or addition of one or more other portions and/or steps and/or segments, and/or features thereof.

Example embodiments of the present invention are described herein with reference to drawings that are schematic illustrations of idealized embodiments of the present invention. As such, variations from the shapes of the illustrations as a result, for example, of a noise or a signal's attenuation in circuits and memory array, are to be expected. Thus, example embodiments of the present invention should not be construed as limited to the particular shapes of regions illustrated herein but are to include deviations in shapes that result, for example, from signals processing. Thus, the portions illustrated in the figures are schematic in nature and their shapes are not intended to illustrate the actual shape of a signal portion and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein in connection with the description of the invention, the term “about” means+/−10%. By way of example, the phrase “about 100” indicates a range of between 90 and 110. With the above embodiments in mind, it should be understood that the invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Any of the operations described herein that form portions and/or steps and/or segments of the invention are useful operations. The invention also relates to a device or an apparatus for performing these operations. The apparatus may be specially constructed for the required purposes, or it may be a general-purpose apparatus. In particular, various general-purpose or apparatus may be used with computer programs written in accordance with the teachings herein, or it may be more convenient to construct a more specialized apparatus to perform the required operations.

It will be further appreciated that the instructions represented by the operations in the above figures are not required to be performed in the order illustrated, and that all the processing represented by the operations may not be necessary to practice the invention. Further, the processes described in any of the above figures can also be implemented in the specially constructed or/and general-purpose apparatus.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

While the above description contains specificities, these should not be construed as limitations on the scope of any embodiment, but as exemplifications of the presently preferred embodiments thereof. Many other ramifications and variations are possible within the teachings of the various embodiments. Thus the scope of the invention should be determined by the appended claims and their legal equivalents, and not by the examples given.

The invention utilizes properties of microwave fields that do not depend on the type of non-volatile memory. Some parameters of MWF such as frequency or amplitude or duration should be tuned to the particular architecture of a memory device regardless of the type of memory. Anybody skilled in the art can easily figure out best values of the properties for particular memory. Therefore, most of the claims of the invention are applicable to different types of memory such as

It should be appreciated that the embodiments of the invention can be implemented in different resistive memories selected from the group consisting of a PCM, a MRAM, a FeRAM, a PMC, molecular memory, polymer memory, ion-conducting memory, memristive memory, spin memory, and a RRAM.

### CONCLUSION

The main advantage of some embodiments of this invention is the low current during reset pulse which amplitude is comparable with the set current and short set pulse which duration is comparable with the reset pulse.

Proposed in some embodiments of this invention reset pulses allow program PCM devices without spending large energy for PCA melting, and without degradation of PCA by electro-diffusion of electrodes into molten material.

Proposed in some embodiments of this invention set pulses allow accomplish high speed of PCM memory programming, and as the result makes PCM competitive with high performance DRAM memories.

Proposed in some embodiments of this invention compounds allow microwave fields affect a memory device stronger.

Proposed in some embodiments of this invention memory storage and retrieval devices allow effective programming by pulses coupled with microwave fields.

Proposed apparatus implements methods or/and devices proposed in some embodiments of this invention

I claim:

1. A method of operating a memory device programmable to a plurality of states
by a pulse coupled with
a microwave electromagnetic field.

2. The method of claim 1, wherein said memory device selected from the group consisting of a phase-change memory (PCM, PRAM, PCRAM, PC-RAM), a resistive memory (RRAM), a magnetoresistive memory (MRAM), a polymer memory (PRAM), a molecular memory, a ferroelectric memory (FeRAM), an ionic memory (PMC), a memristive memory, a spin memory, an oxide memory such as ReRAM, OxRAM, RRAM, a conductive bridging random access memory (CBRAM).

3. The method of claim 1, wherein said pulse is square or/and is non-rectangular or/and has a free-shape with uniform or non-uniform segments; or/and has a single polarity or/and is a bipolar; or/and consist of one or more trains of pulses; or/and said pulse is an electrical current; or/and an electrical voltage; or/and is a non-electrical signal selected from the group consisting of pressure, heat, acoustic or magnetic field, or gravity force.

4. The method of claim 1, wherein said plurality of states includes one or more reset states there a subsystem of said phase change alloy is mostly disordered, and one or more set states there the subsystem of said phase change alloy is at least partially ordered; and in some embodiments said subsystem is the atomic system or/and the electron system or/and the dipole system or/and the magnetic system or/and the subsystem of excitations.

5. The method of claim 3, wherein one or more said set states, have one or more properties with values below a predetermined value for this property; and one or more said reset states, have one or more properties with values above the predetermined value for this property, there the property can be selected from the group consisting of electrical resistance, electrical impedance, threshold switching voltage, electrical capacitance, electrical inductance, optical reflection, electron spin resonance signal.

6. The method of claim 1, wherein said microwave electromagnetic field has constant amplitude during said pulse; or amplitude of said microwave electromagnetic field changes during said pulse; or said microwave electromagnetic field has variable amplitude during said pulse; or/and said microwave electromagnetic field has constant frequency during said pulse; or said microwave electromagnetic field has variable frequency during said pulse or said frequency of said microwave electromagnetic field changes during said pulse; or/and said microwave electromagnetic field has frequency between 300 MHz and 300 GHz; or/and said frequency of said microwave electromagnetic field corresponds to maximum non-thermal microwave heating effect for said set state of said phase change alloy; or/and said frequency of said microwave electromagnetic field corresponds to maximum non-thermal microwave crystallization effect for said reset state of said phase change alloy.

7. The method of claim 1, wherein a duration of said pulse coupled with said microwave electromagnetic field is shorter that duration of a pulse without said microwave electromagnetic field, and said duration of said pulse without said microwave electromagnetic field is long enough to crystallize a portion of said phase-change alloy in said memory device during said programming of said memory in any of said set states; and in some embodiments said pulse coupled with said microwave electromagnetic field programs said phase-change memory in said set states with relatively small resistance and threshold voltage to compare with said reset states;
or/and an amplitude of said pulse coupled with said microwave electromagnetic field is smaller than an amplitude of a pulse without said microwave electromagnetic field, and said amplitude of said pulse without said microwave electromagnetic field is big enough to melt a portion of said phase-change alloy in said memory device during said programming of said memory in any of said reset states; and in some embodiments
said pulse coupled with said microwave electromagnetic field programs said phase-change memory in said reset states with relatively large resistance and threshold voltage to compare with said set states.

8. A compound compromising
host material capable to reversible transition between two or more non-volatile states, and
susceptor dispersing in the body of said host material, and
said susceptor increases efficiency of a microwave electromagnetic field coupling with said host material.

9. The compound of claim 8, wherein said host material selected from the group consisting of an inorganic, an organic, a polymer, a metal-oxide, an ion conductor, a ferroelectric, a perovskite, a magnetoresistive alloy, a Mott insulator, a chalcogenide alloy (that for example contains tellurium or a pnictide such as antimony), a phase change alloy compromises of chemical elements selected from the group consisting of Ge, Si, As, Sb, Te, Se, Ga, Sn, Bi, and In; while said susceptor selected from the group consisting of an inorganic, an organic, a polymer, electrostrictive material such as (lead magnesium niobate (PMN), lead magnesium niobate-lead titanate (PMN-PT), and lead lanthanum zirconate titanate (PLZT) or their compounds), C, SiC, water, Mn, Co, Cr, Fe, Cu, Zn, Ti, Hf, V, Cd and Ni.

10. The compound of claim 8, wherein said susceptor does not chemically interact with said host material even in molten state or/and has higher melting temperature than a melting temperature of said host material.

11. The compound of claim 8, wherein said host material and said susceptor coupled together by a mixing or by a co-deposition or by a co-melting; or one or more from these methods coupled said host with one or more susceptors.

12. A memory storage and retrieval device compromising
at least one active material coupled with
one or more electrodes, and
said active material contains a susceptor dispersing in the body of said active material.

13. The device of claim 12, wherein said active material selected from the group consisting of an inorganic, an organic, a polymer, a metal-oxide, an ion conductor, a ferroelectric, a perovskite, a magnetoresistive alloy, a Mott insulator, a chalcogenide alloy (that for example contains tellurium or a pnictide such as antimony), a phase change alloy compromises of chemical elements selected from the group consisting of Ge, Si, As, Sb, Te, Se, Ga, Sn, Bi, and In; while said susceptor selected from the group consisting of an inorganic, an organic, a polymer, electrostrictive material such as (lead magnesium niobate (PMN), lead magnesium niobate-lead titanate (PMN-PT), and lead lanthanum zirconate titanate (PLZT) or their compounds), C, SiC, water, Mn, Co, Cr, Fe, Cu, Zn, Ti, Hf, V, Cd and Ni; and in some embodiments said active material and said susceptor coupled together by a method selected from the group consisting of mixing, co-deposition, and co-melting.

14. The device of claim 12, wherein said susceptor does not chemically interact with said active material even in the molten state; and/or said susceptor has higher melting temperature than a melting temperature of said active material.

15. The device of claim 12, wherein said active material consists one or more films (e.g., of a phase change alloy) layered between said first electrode and said second electrode (e.g., one or both said electrodes are made from one or several layers of relatively conductive materials) and at least one of said films has susceptor dispersing in the body of this film; and in some embodiments said film is deposited on the surface of one of said electrodes.

16. The device of claim 12, wherein thermal expansion coefficient of at least one of said electrodes is lower than thermal expansion coefficient of said active material with said susceptor dispersing in the body of said alloy; or/and compressibility of at least one of said electrodes is lower than compressibility of said active material with said susceptor dispersing in the body of said alloy; or/and hardness of at least one of said electrodes is higher than hardness of said active material with said susceptor dispersing in the body of said active material.

17. The device of claim 12, wherein said active material consists of at least one pnictogen (for example, Sb) and at least one chalcogen (for example, Te) and can contain one or more chemical elements (for example, H, F, In, Sn, Bi) that form atomic bond with a pnictogen or/and a chalcogen with energy smaller than the energy of the bond between said pnictogen and chalcogen, and the atomic structure of said active material is easily deformable by external pressure due to due to significant concentration of vacancies (above 1% of atomic sites, but below 85%).

18. An apparatus comprising:
a write circuit coupled with a resistive memory; and
a microwave generator coupled with said memory or with said write circuit; and
other interface devices coupled with said memory, and/or with said microwave generator, and/or with said write circuit.

19. The apparatus of claim 18, wherein said write circuit and said microwave generator allow programming said resistive memory according to claim 1; or/and resistive memory (e.g., a phase change memory) consisting of one or more of said memory storage and retrieval devices according to claim 12; or/and said microwave generator embedded in said write circuit.
